(19) United States
(12) Patent Application Publication
(10) Pub. No.: US 2024/0145371 A1
(43) Pub. Date: May 2, 2024

(54) POWER MODULE AND METHOD OF MANUFACTURING THE SAME

(71) Applicants: Hyundai Motor Company, Seoul (KR); Kia Corporation, Seoul (KR)

(72) Inventors: So Eun JEONG, Hwaseong-si (KR); Suk Hyun LIM, Hwaseong-si (KR)

(73) Assignees: Hyundai Motor Company, Seoul (KR); Kia Corporation, Seoul (KR)

(21) Appl. No.: 18/134,684

(22) Filed: Apr. 14, 2023

(30) Foreign Application Priority Data
Oct. 27, 2022 (KR) 10-2022-0140628

(51) Int. Cl. H01L 23/498; H01L 23/00; H01L 23/46

(52) U.S. Cl. CPC H01L 23/49838; H01L 23/46; H01L 23/49833; H01L 24/32; H01L 24/48; H01L 24/73; H01L 24/83; H01L 24/92; H01L 25/072

(57) ABSTRACT

A power module and a method of manufacturing the same, includes at least one insulating substrate; and at least one semiconductor chip included on the at least one insulating substrate, the at least one insulating substrate including: an insulating layer; and a metal layer disposed between the at least one semiconductor chip and the insulating layer, forming electrical connection with the at least one semiconductor chip through a circuit pattern, and allowing a fluid filled in a sealed cavity formed in the metal layer to flow.

### CROSS REFERENCE TO RELATED APPLICATION

The present application claims priority to Korean Patent Application No. 10-2022-0140628, filed Oct. 27, 2022, the entire contents of which is incorporated herein for all purposes by this reference.

### BACKGROUND OF THE PRESENT DISCLOSURE

### Field of the Present Disclosure

The present disclosure relates to a power module, and more to a power module and a method of manufacturing the same, which can effectively dissipate heat generated in a semiconductor chip through a structure including a substrate in which fluid flows and a manufacturing method thereof.

### Description of Related Art

Eco-friendly vehicles using an electric motor as a power source are increasing as interest in the environment has recently increased. The eco-friendly vehicle is also called an electrified vehicle, and an electric vehicle (EV) and a hybrid electric vehicle (HEV) are representative examples of the eco-friendly vehicle.

Such an electrified vehicle includes an inverter to convert DC power into AC power when the motor operates, and the inverter generally includes one or a plurality of power modules having a semiconductor chip to perform a switching function.

Meanwhile, the power module having the at least one semiconductor chip to perform the switching function involves heat generation of the at least one semiconductor chip as a high voltage is applied thereto or a large amount of current flows therein during operation. For stable operations of the power module, it is necessary to dissipate heat. To the present end, various methods have been used.

As one of them, there is a method of transferring heat generated in the at least one semiconductor chip to the substrate, and dissipating the heat through a cooling channel connected to the power module, cooling the power module.

However, a conventional heat dissipation method has a limited range of transferring heat generated in the at least one semiconductor chip. Accordingly, there is a demand for a method of more efficiently dissipating heat generated in the power module.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a power module and a method of manufacturing the same, which can effectively dissipate heat generated in the power module.

Technical problems to be solved in an exemplary embodiment of the present disclosure are not limited to the forementioned technical problems, and other unmentioned technical problems may be clearly understood from the following description by a person having ordinary knowledge in the art to which the present disclosure pertains.

According to an exemplary embodiment of the present disclosure, a power module includes at least one insulating substrate; and at least one semiconductor chip included on the at least one insulating substrate, in which the at least one insulating substrate includes: an insulating layer; and a metal layer disposed between the at least one semiconductor chip and the insulating layer, forming electrical connection with the at least one semiconductor chip through a circuit pattern, and allowing a fluid filled in a sealed cavity formed in the metal layer to flow.

For example, the metal layer may include a chamber forming the cavity; and an inlet formed at least one side of the chamber in a horizontal direction and closed in a state where the fluid is filled in the cavity.

For example, the inlet may extend from the chamber to protrude from the insulating layer on a plane.

For example, the fluid may be filled in the cavity in a state that the at least one semiconductor chip and the at least one insulating substrate are bonded.

For example, the fluid may be filled in the cavity in a state that the at least one semiconductor chip and the at least one insulating substrate are bonded, and a filling material is filled to surround at least a portion of the at least one insulating substrate and external surfaces of the at least one semiconductor chip.

For example, the at least one insulating substrate may further include a heat dissipation layer spaced from the metal layer through the insulating layer.

For example, the at least one insulating substrate may include a first insulating substrate and a second insulating substrate which are spaced from and opposite to each other in a vertical direction with the at least one semiconductor chip therebetween.

For example, at least one of the first insulating substrate and the second insulating substrate may further include a protrusion protruding from a portion of the chamber, which faces a power pad of the at least one semiconductor chip, toward the at least one semiconductor chip in a vertical direction to further space the insulating layer apart from the at least one semiconductor chip as much as a protruding thickness.

For example, the power module may further include a signal lead and a power lead, wherein the signal lead is connected to a signal pad of the at least one semiconductor chip through a conductor.

According to an exemplary embodiment of the present disclosure, a method of manufacturing a power module includes preparing at least one insulating substrate by bonding a metal layer, which includes a chamber and an inlet, to a first side of an insulating layer; bonding the at least one semiconductor chip onto the metal layer; injecting a fluid into a cavity formed in the metal layer through the inlet after the bonding; and closing the inlet after injecting the fluid.

For example, the method may further include filling a filling material to surround at least a portion of the at least one insulating substrate and external surfaces of the at least one semiconductor chip, between the bonding and the injecting of the fluid.

For example, the method may further include bonding a signal lead and a power lead to the metal layer after preparing the at least one insulating substrate.

For example, the method may further include connecting a signal pad of the at least one semiconductor chip and the signal lead through a conductor, after bonding each of the signal lead and the power lead.

For example, the preparing the at least one insulating substrate includes bonding a heat dissipation layer to a second side opposite to the first side of the insulating layer.

For example, the preparing of the at least one insulating substrate may include preparing a first insulating substrate and a second insulating substrate, and the bonding may include bonding the first insulating substrate and the second insulating substrate to be spaced from and opposite to each other in a vertical direction with the at least one semiconductor chip therebetween.

Problems according to an exemplary embodiment of the present disclosure may not be limited by the aforementioned problems, and other unmentioned problems may be clearly understood from the following description by those skilled in the art.

As described above, according to various embodiments of the present disclosure, the fluid is allowed to flow inside the substrate that transfers heat generated in the power module to the outside thereof, improving heat transfer efficiency.

Therefore, the cooling efficiency of the power module is improved so that the power module can operate stably at a relatively low temperature.

Furthermore, the fluid is injected into the substrate after a high-temperature process, alleviating the risk and limitations during the process, and widening the choice for the fluid injected into the substrate.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 and FIG. 2 are cross-sectional views showing a power module according to an exemplary embodiment of the present disclosure.

FIG. 3 is a flowchart illustrating a process of manufacturing a power module according to an exemplary embodiment of the present disclosure.

FIG. 4, FIG. 5, FIG. 6, FIG. 7, FIG. 8, FIG. 9, FIG. 10 and FIG. 11 are cross-sectional views sequentially showing a process of manufacturing a power module according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, Hereinafter, various embodiments of the present disclosure will be described in detail with reference to the accompanying drawings, in which the same or similar elements are denoted by the same reference numerals even though they are depicted in different drawings and redundant descriptions thereof will be avoided. Suffixes “module” and “unit” put after elements in the following description are provided in consideration of only ease of description and do not have meaning or functions discriminated from each other. In terms of describing the exemplary embodiments of the present disclosure, detailed descriptions of related art will be omitted when they may make the subject matter of the exemplary embodiments of the present disclosure rather unclear. Furthermore, the accompanying drawings are provided only for a better understanding of the exemplary embodiments of the present disclosure and are not intended to limit technical ideas of the present disclosure. Therefore, it should be understood that the accompanying drawings include all modifications, equivalents and substitutions within the scope and spirit of the present disclosure.

Terms such as “first” and “second” may be used to describe various components, but the components should not be limited by the above terms. Furthermore, the above terms are used only for distinguishing one component from another.

When it is described that one component is “connected” or “joined” to another component, it should be understood that the one component may be directly connected or joined to another component, but additional components may be present therebetween. However, when one component is described as being “directly connected,” or “directly coupled” to another component, it should be understood that additional components may be absent between the one component and another component.

Unless the context clearly dictates otherwise, singular forms include plural forms as well.

In an exemplary embodiment of the present disclosure, it should be understood that term “include” or “have” indicates that a feature, a number, a step, an operation, an element, a part, or the combination thereof described in the exemplary embodiments is present, but does not preclude a possibility of presence or addition of one or more other features, numbers, steps, operations, elements, parts or combinations thereof, in advance.

According to an exemplary embodiment of the present disclosure, it is provided to widen the range of choice for fluid 800 and thus improve processibility and thermal performance by allowing the fluid 800 to flow inside a metal layer 120 of an insulating substrate 100, and preventing the fluid 800 from being heated to a high temperature in a process.

Meanwhile, a thermal resistance concept may be used as a thermal performance indicator of the power module. The thermal resistance depends on the arrangement of parts and the properties of materials. The lower the thermal resistance, the higher the efficiency of dissipating heat generated in a chip.

Furthermore, to improve the thermal performance, it is required to secure a larger heat dissipation area in the power module. Securing the heat dissipation area largely leads to expanding a module structure or widening material choice, affecting the size and price of the power module.

Meanwhile, a heat dissipation angle depends on the properties of materials used in the power module. Under the condition that the heat dissipation angle is constant, the heat dissipation area becomes larger and the thermal performance is more improved as the thickness of the material increases.

However, an exemplary embodiment of the present disclosure, the fluid is allowed to flow inside the substrate, so that the heat dissipation area may be enlarged without changing the thickness of the materials despite the heat dissipation angle depending on the properties of materials.

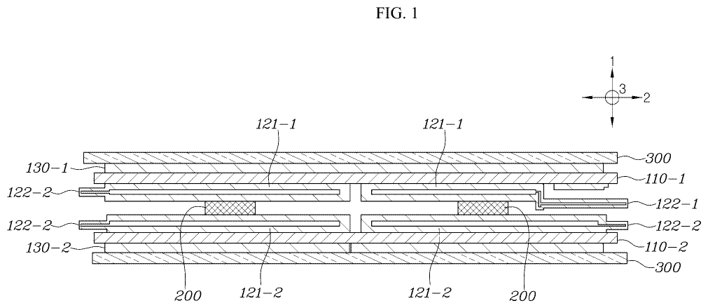

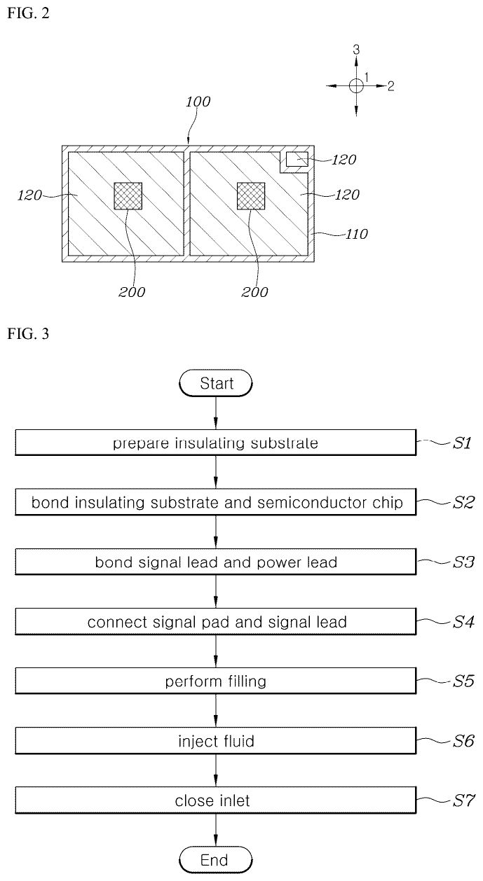

Below, the configuration and structure of a power module improved in processibility and thermal performance according to an exemplary embodiment of the present disclosure will be first described with reference to FIG. 1 and FIG. 2.

FIG. 1 and FIG. 2 are cross-sectional views showing a power module according to an exemplary embodiment of the present disclosure. FIG. 1 is the cross-sectional view of the power module according to an exemplary embodiment viewed in a third axial direction, and FIG. 2 is the cross-sectional view of the power module according to an exemplary embodiment viewed in a first axial direction thereof.

Referring to both FIG. 1 and FIG. 2, the power module according to various exemplary embodiments of the present disclosure may include at least one insulating substrate 100, at least one semiconductor chip 200, and a cooling channel 300. FIG. 1 and FIG. 2 mainly show elements related to the present disclosure, and an actual power module may of course be implemented including more or less elements than those shown in FIG. 1 and FIG. 2. Below, the elements will be described.

First, the insulating substrate 100 may include the insulating layer 110, the metal layer 120 and a heat dissipation layer 130.

The insulating layer 110 is configured to electrically insulate the inside and outside of the power module, while receiving or transferring heat from a metal material adhered to one surface or both surfaces thereof.

The metal layer 120 is disposed between one surface of the semiconductor chip 200 and one surface of the insulating layer 110 in a vertical direction (i.e., the first axial direction), and may form an electrical connection with the semiconductor chip 200 through a circuit pattern.

Furthermore, the metal layer 120 has a cavity formed therein and filled with the fluid 800 so that the fluid 800 can flow within the sealed cavity.

The metal layer 120 transfers heat generated in the semiconductor chip 200 to the outside through the insulating layer 110 and the like. The higher the heat transfer efficiency of the metal layer 120, the higher the cooling efficiency of the power module. With the higher cooling efficiency, the power module can operate more stably.

As the area where the metal layer 120 allows the fluid 800 to flow therein is in contact with the semiconductor chip 200 and the insulating layer 110 becomes larger, the range of transferring heat generated in the semiconductor chip 200 to the insulating layer 110 increases. Furthermore, a heat transfer range for the heat dissipation layer 130 (to be described later) is expanded, improving the cooling efficiency of the power module.

Meanwhile, the fluid filled in the cavity may, for example, include a volatile fluid such as water vapor, methanol, and acetone. Besides, the fluid may be suitably selected according to a target internal temperature of the power module, a target thermal conductivity of the power module, etc.

The metal layer 120 may include a chamber 121 and an inlet 122 to form the cavity.

The inlet 122 refers to an intake for injecting the fluid 800 into the cavity of the metal layer 120, and may be formed on at least one side of the chamber 121 in a horizontal direction (i.e., a second or third axial direction).

The inlet 122 is closed in a state that the fluid 800 is injected into the cavity, so that the fluid 800 can flow inside the sealed metal layer 120.

The inlet 122 may be formed extending from the chamber 121 to protrude from the insulating layer 110 on a plane. The inlet 122 protruding as above makes it convenient to inject the fluid 800.

Meanwhile, the fluid 800 may be filled in the cavity in the state that the insulating layer 110 and the metal layer 120 are bonded to form the insulating substrate 100, and the semiconductor chip 200 and the insulating substrate 100 are bonded.

Furthermore, the fluid 800 may be filled in the cavity in the state that the semiconductor chip 200 and the insulating substrate 100 are bonded and a filling material is filled to surround at least a portion of the insulating substrate 100 and the external surfaces of at least one semiconductor chip 200.

With the present configuration, it is possible to avoid a high temperature heating process which may be involved in the bonding and filling of the power module, preventing a risk such as an explosion of the metal layer 120 in a processing process, and being free from limitations of a processing temperature so that more various kinds of fluid 800 may be appropriately applied to the power module as necessary.

Meanwhile, the insulating substrate 100 may further include the heat dissipation layer 130, and the heat dissipation layer 130 may be disposed being spaced from the metal layer 120 through the insulating layer 110. In other words, the heat dissipation layer 130 may be disposed on a second surface opposite to a first surface (on which the metal layer 120 is disposed) of the insulating layer 110 in a vertical direction (i.e., the first axial direction). Thus, a stacking structure of the heat dissipation layer 130—the insulating layer 110—the metal layer 120 may be formed.

The heat dissipation layer 130 may be made of a metal material, and receive heat generated in the semiconductor chip 200 via the metal layer 120 and the insulating layer 110.

The heat dissipation layer 130 dissipates the received heat through heat exchange with the outside thereof, cooling the power module, and thus lowering the operation temperature of the module.

For example, the metal layer 120 and the heat dissipation layer 130 may be made of copper (Cu), and the insulating layer 110 may be made of ceramic. In the instant case, the insulating substrate 100 may be implemented by an active metal brazed (AMB) substrate or a direct bonded copper (DBC) substrate according to bonding methods.

Furthermore, as shown in FIG. 2, a portion of the metal layer 120 may be separated and disposed on the insulating layer 110.

Meanwhile, the shape of the metal layer 120 may be changeable as long as a circuit pattern for electrical connection is maintained, and the area of the metal layer 120 excluding the inlet 122 is limited within the area of the insulating layer.

Meanwhile, the semiconductor chip 200 is disposed on at least one insulating substrate 100.

The semiconductor chip 200 may be turned on or off in response to a switching signal, and electrically connect or disconnect the upper and lower surfaces thereof.

Here, the switching signal may be input in a form of voltage through a signal pad provided in the semiconductor chip 200. When the switching signal is input, the upper and lower surfaces of the semiconductor chip 200 are electrically connected so that current can flow in a power pad.

Meanwhile, the semiconductor chip 200 may, for example, include an insulated gate bipolar transistor (IGBT), a metal-oxide-semiconductor field-effect transistor (MOSFET), or the like switching device.

Furthermore, the material of the semiconductor chip 200 may contain silicon (S1) or silicon carbide (SiC). Silicon carbide improves energy efficiency or reduces the volume or weight of the module as compared with silicon.

Furthermore, as shown in FIG. 1 and FIG. 2, the power module may include a plurality of semiconductor chips 200 mounted therein by a flip chip or reverse structure according to internal structures thereof.

Furthermore, to more effectively dissipate heat, the cooling channel 300 may be additionally provided outside the insulating substrate 100 of the power module. The cooling channel 300 may, for example, be based on an air-cooling type or a water-cooling type, and a refrigerant may be used to improve cooling efficiency.

Meanwhile, the power module may be classified into a single-sided cooling type and a double-sided cooling type according to cooling methods.

In the single-sided cooling type, the insulating substrate 100 is disposed on one side of the semiconductor chip 200 and heat dissipates only in one direction thereof. In the double-sided cooling type, the insulating substrates 100 are disposed on both sides of the semiconductor chip 200 and heat dissipates upwards and downwards.

The power module according to an exemplary embodiment of the present disclosure may be applied to both the single-sided cooling type and the double-sided cooling type. In the case of the double-sided cooling type power module, the insulating substrate 100 may include a first insulating substrate 110-1 and a second insulating substrate 110-2, which are spaced from and opposite to each other with the semiconductor chip 200 therebetween in the vertical direction (i.e., the first axial direction).

For example, the first insulating substrate 110-1 may be disposed on a first side of the semiconductor chip 200, and the second insulating substrate 110-2 may be disposed on a second side of the semiconductor chip 200 provided with the power pad.

Alternatively, in the case of using the flip chip or reverse structure, a first side of one semiconductor chip and a second side of another semiconductor chip among the plurality of semiconductor chips 200 are disposed together on the first insulating substrate 110-1, and the second insulating substrate 110-2 may be disposed on the semiconductor chips 200.

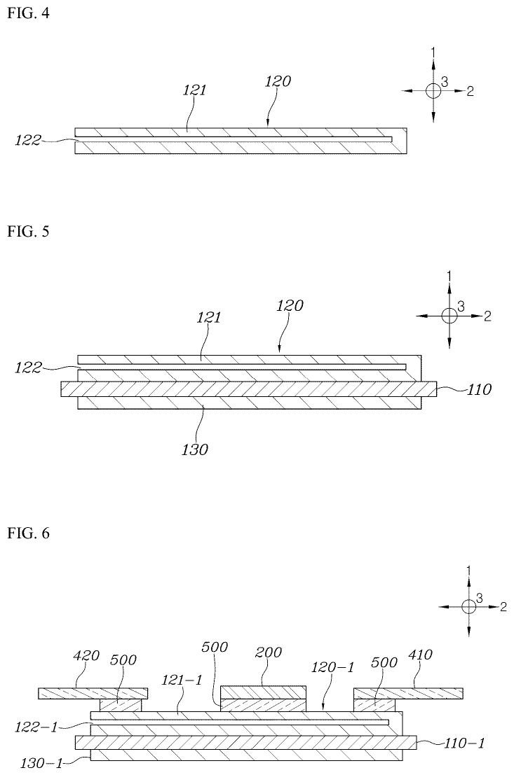

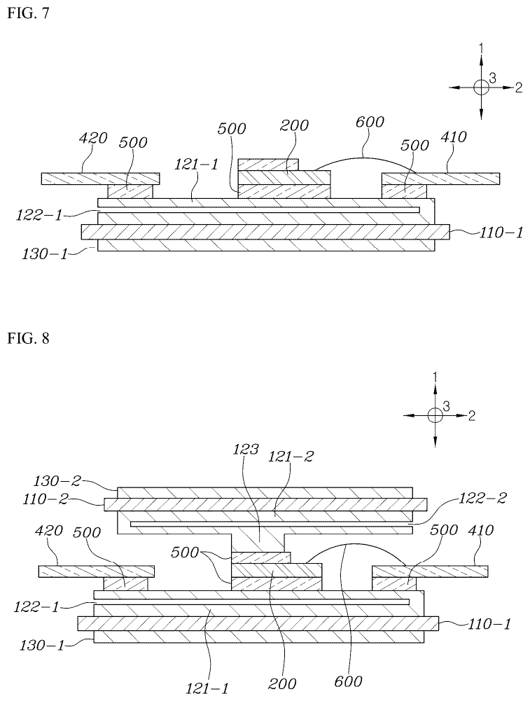

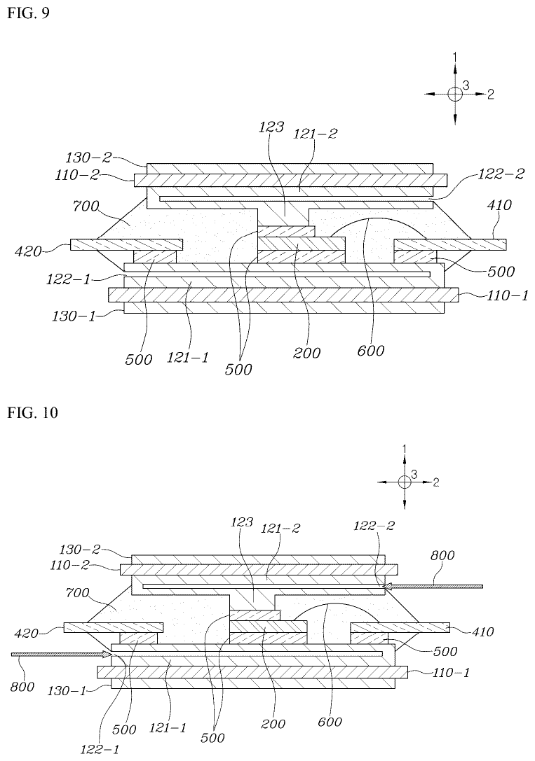

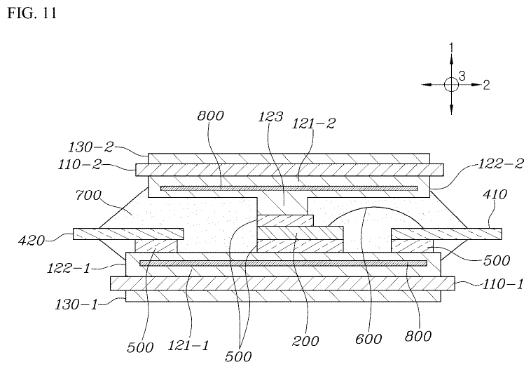

Below, the elements of the power module according to an exemplary embodiment will be described with respect to additional features thereof and their manufacturing processes with reference to FIG. 3, FIG. 4, FIG. 5, FIG. 6, FIG. 7, FIG. 8, FIG. 9, FIG. 10 and FIG. 11.

FIG. 3 is a flowchart illustrating a process of manufacturing a power module according to an exemplary embodiment of the present disclosure, and FIG. 4, FIG. 5, FIG. 6, FIG. 7, FIG. 8, FIG. 9, FIG. 10 and FIG. 11 are cross-sectional views sequentially showing a process of manufacturing a power module according to an exemplary embodiment of the present disclosure.

Referring to FIG. 3, a manufacturing process of a power module according to an exemplary embodiment of the present disclosure includes steps of preparing an insulating substrate (S1), bonding the insulating substrate and a semiconductor chip (S2), bonding a signal lead and a power lead (S3), connecting the signal pad and the signal lead (S4), applying a filling material (S5), injecting fluid and sealing an inlet (S6). FIG. 3 mainly shows the elements related to the present disclosure, and the manufacturing process for an actual power module may of course be implemented including more or less processes than those shown in FIG. 3. Below, the processes will be described.

Prior to manufacturing the power module in earnest, the insulating substrate 100 is provided (S1).

Referring to FIG. 4, the metal layer 120 may be provided including the chamber 121 and the inlet 122. Here, the inlet 122 of the metal layer 120 may be opened, and the cavity formed through the chamber 121 may be empty.

Referring to FIG. 5, the metal layer 120 may be bonded to a first side of the insulating layer 110, and the heat dissipation layer 130 may be additionally bonded to a second side of the insulating layer 110 opposite to the first side, preparing the insulating substrate 100 including the stacking structure of the heat dissipation layer 130—the insulating layer 110—the metal layer 120.

In the instant case, the bonding between the metal layer 120 or the heat dissipation layer 130 and the insulating layer 110 may be based on an AMB method or an DBC method.

After preparing the insulating substrate 100 (S1), at least one semiconductor chip 200 may be bonded onto the metal layer 120, bonding the insulating substrate 100 and the semiconductor chip 200 (S2).

Furthermore, a signal lead 410 and a power lead 420 may be additionally bonded to the insulating substrate 100 (S3).

After the signal lead 410 and the power lead 420 are bonded to the insulating substrate 100, the signal pad and the signal lead 410 of the semiconductor chip 200 may be connected by a conductor (S4).

Referring to FIG. 6, the semiconductor chip 200 may be bonded onto the metal layer 120 by a bonding material 500, and the signal lead 410 and the power lead 420 may also be bonded to the metal layer 120 by the bonding material 500.

Furthermore, in the instant case, the bonding between the metal layer 120 and each of the semiconductor chip 200, the signal lead 410, and the power lead 420 may be based on soldering or sintering.

For example, each lower surface of the semiconductor chip 200, the signal lead 410 and the power lead 420 may be soldered onto the first insulating substrate 110-1. In the instant case, the power pad and the signal pad formed on the upper surface of the semiconductor chip 200 may not be bonded to the metal layer 120-1 of the first insulating substrate.

Referring to FIG. 7, the signal pad formed on the upper surface of the semiconductor chip 200 and the signal lead 410 bonded to the upper surface of the metal layer 120-1 of the first insulating substrate may be connected by wire bonding. Alternatively, the signal pad and the signal lead 410 may be connected by clip bonding unlike that shown in FIG. 7.

Meanwhile, referring to FIG. 8, for the double-sided cooling type, the second insulating substrate 110-2 may be bonded onto the semiconductor chip 200. In the instant case, the metal layer 120-2 of the second insulating substrate and the semiconductor chip 200 may be bonded by soldering or sintering, and the metal layer 120-2 of the second insulating substrate may be connected to the power pad of the semiconductor chip 200.

Furthermore, the first insulating substrate and the second insulating substrate may further include a protrusion 123 protruding from a portion of the chamber 121-1 or 121-2, which faces the power pad of the semiconductor chip 200, toward the semiconductor chip 200 in the vertical direction (i.e., in the first axial direction), so that the insulating layer 110-1 or 110-2 may be further spaced from the semiconductor chip 200 as much as a protruding thickness Ti.

The protrusion 123 may be bonded to the power pad of the semiconductor chip 200, and make heat generated in the semiconductor chip 200 be first transferred in the vertical direction (i.e., the first axial direction), improving heat transfer efficiency.

After the signal pad and the signal lead 410 of the semiconductor chip 200 are connected (S4), a filling process for filling a filling material to surround at least a portion of the insulating substrates 110-1 and 110-2 and the external surfaces of at least one semiconductor chip 200 (S5).

Referring to FIG. 9, a filling material 700 is injected into an internal space between the first insulating substrate 110-1 and the second insulating substrate 110-2, and thus filled to surround at least a portion of the first insulating substrate 110-1 and the second insulating substrate 110-2 and the external surfaces of the semiconductor chip 200. Furthermore, in the instant case, the filling material 700 may also be filled to surround an exposure region above the semiconductor chip 200.

After the filling process (S5), the fluid 800 is injected into the cavity formed by the chamber 121 (S6). After the injection is completed, the inlet 122 is closed (S7).

Referring to FIG. 10, the fluid 800 may be injected into the cavities through the inlets 122-1 and 122-2 in the state that the internal space between the first insulating substrate 110-1 and the second insulating substrate 110-2 is filled with the filling material.

As the fluid 800 is injected into the metal layer 120 after completing a high temperature heating process which may be involved in the bonding and filling of the power module, it is possible to prevent a risk such as an explosion of the metal layer 120 in a processing process, and be free from limitations of a processing temperature so that more various kinds of fluid 800 may be appropriately applied to the power module as necessary.

Referring to FIG. 11, the inlets 122-1 and 122-2 are closed after the cavities are filled with the fluid 800, so that the fluid can flow inside the sealed metal layer 120 during the operation of the power module.

Here, the reference numerals 130-1 and 130-2 refer to the heat dissipation layers.

As described above, according to various embodiments of the present disclosure, the fluid is allowed to flow inside the substrate that transfers heat generated in the power module to the outside thereof, improving heat transfer efficiency.

Therefore, the cooling efficiency of the power module is improved so that the power module can operate stably at a relatively low temperature.

Furthermore, the fluid is injected into the substrate after a high-temperature process, alleviating the risk and limitations during the process, and widening the choice for the fluid injected into the substrate.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A power module comprising:
at least one insulating substrate; and
at least one semiconductor chip disposed on the at least one insulating substrate,
wherein the at least one insulating substrate includes:
an insulating layer; and
a metal layer disposed between the at least one semiconductor chip and the insulating layer, forming electrical connection with the at least one semiconductor chip through a circuit pattern, and allowing a fluid filled in a sealed cavity formed in the metal layer to flow therein.

2. The power module of claim 1, wherein the metal layer includes:
a chamber forming the cavity; and
an inlet formed at at least one side of the chamber and closed in a state that the fluid is filled in the cavity.

3. The power module of claim 2, wherein the inlet extends from the chamber to protrude from the insulating layer on a plane.

4. The power module of claim 2, wherein the fluid is filled in the cavity in a state that the at least one semiconductor chip and the at least one insulating substrate are bonded.

5. The power module of claim 4, wherein the fluid is filled in the cavity in a state that the at least one semiconductor chip and the at least one insulating substrate are bonded, and a filling material is filled to surround at least a portion of the at least one insulating substrate and external surfaces of the at least one semiconductor chip.

6. The power module of claim 1, wherein the at least one insulating substrate further includes a heat dissipation layer spaced from the metal layer by the insulating layer.

7. The power module of claim 1, wherein the at least one insulating substrate includes a first insulating substrate and a second insulating substrate which are spaced from and opposite to each other in a vertical direction with the at least one semiconductor chip therebetween.

8. The power module of claim 7, wherein at least one of the first insulating substrate and the second insulating substrate further includes a protrusion protruding from a portion of the chamber, which faces a power pad of the at least one semiconductor chip, toward the at least one semiconductor chip in a vertical direction to further space the insulating layer apart from the at least one semiconductor chip as much as a protruding thickness of the protrusion.

9. The power module of claim 8, wherein the protrusion is bonded to the power pad of the at least one semiconductor chip.

10. The power module of claim 1, further including:
a signal lead and a power lead,
wherein the signal lead is connected to a signal pad of the at least one semiconductor chip through a conductor.

11. A method of manufacturing a power module, the method comprising:
preparing at least one insulating substrate by bonding a metal layer, which includes a chamber and an inlet, to a first side of an insulating layer;
bonding the at least one semiconductor chip onto the metal layer;
injecting a fluid into a cavity formed in the metal layer through the inlet after the bonding; and
closing the inlet after injecting the fluid.

12. The method of claim 11, further including filling a filling material to surround at least a portion of the at least one insulating substrate and external surfaces of the at least one semiconductor chip, between the bonding and the injecting of the fluid.

13. The method of claim 11, further including:
bonding a signal lead and a power lead to the metal layer after preparing the at least one insulating substrate.

14. The method of claim 13, further including:
connecting a signal pad of the at least one semiconductor chip and the signal lead through a conductor, after the bonding each of the signal lead and the power lead.

15. The method of claim 11, wherein the preparing of the at least one insulating substrate includes bonding a heat dissipation layer to a second side of the insulating layer opposite to the first side of the insulating layer.

16. The method of claim 11,
wherein the at least one insulating substrate includes a first insulating substrate and a second insulating substrate,
wherein the preparing of the at least one insulating substrate includes preparing the first insulating substrate and the second insulating substrate, and
wherein the bonding includes bonding the first insulating substrate and the second insulating substrate to be spaced from and opposite to each other in a vertical direction with the at least one semiconductor chip therebetween.

17. The method of claim 16, wherein at least one of the first insulating substrate and the second insulating substrate further includes a protrusion protruding from a portion of the chamber, which faces a power pad of the at least one semiconductor chip, toward the at least one semiconductor chip in a vertical direction to further space the insulating layer apart from the at least one semiconductor chip as much as a protruding thickness of the protrusion.

18. The method of claim 17, wherein the protrusion is bonded to the power pad of the at least one semiconductor chip.
